(19) United States
(12) Patent Application Publication
(10) Pub. No.: US 2025/0239561 A1
(43) Pub. Date: Jul. 24, 2025

(54) SEMICONDUCTOR PACKAGE AND METHOD OF FORMING THE SAME

(71) Applicant: Taiwan Semiconductor Manufacturing Company, Ltd., Hsinchu (TW)

(72) Inventors: Chun Chen, New Taipei City (TW); Yung-Ping Chiang, Hsinchu County (TW); Chung-Kuang Lin, Hsinchu City (TW); Chang-Hsuan Lee, Hsinchu County (TW)

(73) Assignee: Taiwan Semiconductor Manufacturing Company, Ltd., Hsinchu (TW)

(21) Appl. No.: 18/415,668

(22) Filed: Jan. 18, 2024

(51) Int. Cl. H01L 23/00; H01L 23/498

(52) U.S. Cl. CPC H01L 24/73; H01L 23/49811; H01L 24/05; H01L 24/11; H01L 24/13; H01L 24/16; H01L 24/27; H01L 24/29; H01L 24/32; H01L 24/92; H01L 2224/0401; H01L 2224/1146; H01L 2224/13111; H01L 2224/13118; H01L 2224/13124; H01L 2224/13139; H01L 2224/13147; H01L 2224/13149; H01L 2224/13155; H01L 2224/13157; H01L 2224/1316; H01L 2224/13166; H01L 2224/13171; H01L 2224/16225; H01L 2224/2784; H01L 2224/2919; H01L 2224/32225; H01L 2224/73204; H01L 2224/92125

(57) ABSTRACT

A method of forming a semiconductor package includes the following operations. A semiconductor die is provided, wherein the semiconductor die includes die connectors protruding from a first side of the semiconductor die. A polymer layer is formed on the first side of the semiconductor die and covers the die connectors. The polymer layer is planarized until surfaces of the die connectors are exposed. The die connectors of the semiconductor die are bonded to interposer connectors of an interposer structure. An underfill layer is formed around the interposer connectors.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor packages have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1A to FIG. 1H are schematic cross-sectional views of a method of forming a semiconductor package in accordance with some embodiments.

FIG. 2A to FIG. 2E are schematic cross-sectional views of a method of forming die connectors of a semiconductor die in accordance with some embodiments.

FIG. 3 to FIG. 5 are schematic cross-sectional views of semiconductor packages in accordance with some embodiments.

FIG. 6 illustrates a method of forming a semiconductor package in accordance with some embodiments.

FIG. 7 illustrates a method of forming a semiconductor package in accordance with some embodiments.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose a semiconductor package and a method of forming the same. By introducing a polymer layer around die connectors of a semiconductor die followed by a planarization process, the die connectors with different heights and connector tilt defects can be resolved simultaneously, so as to improve the connecting property and therefore the package performance.

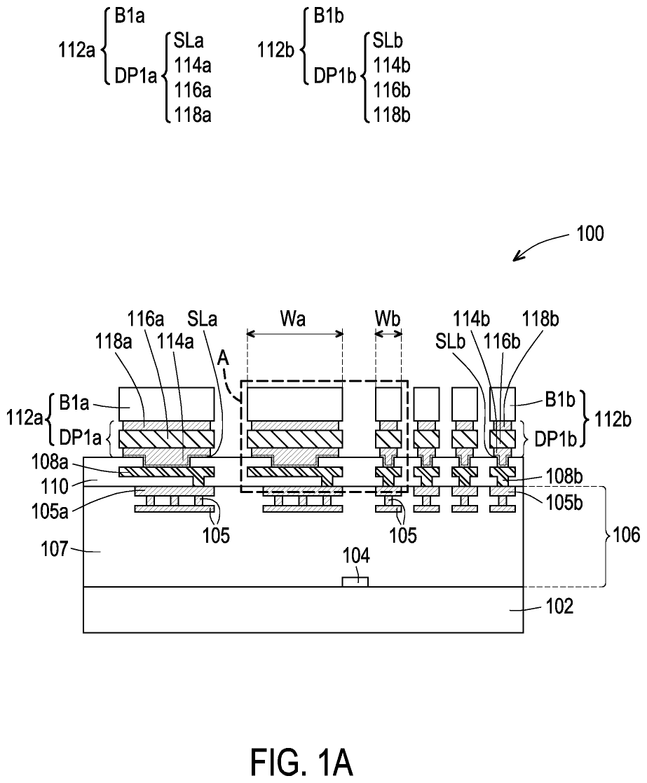

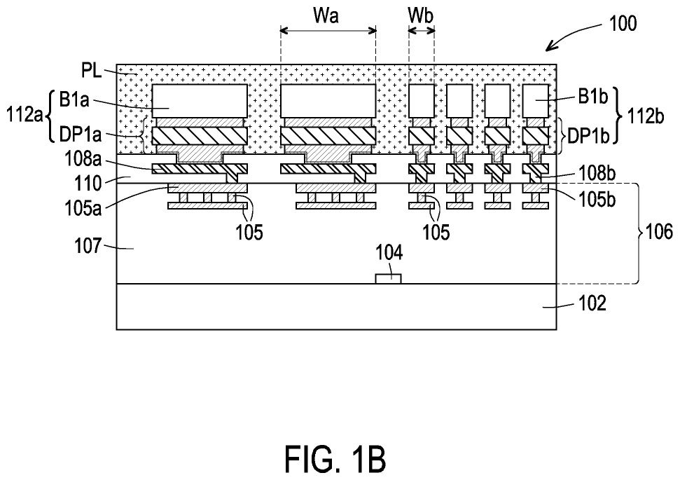

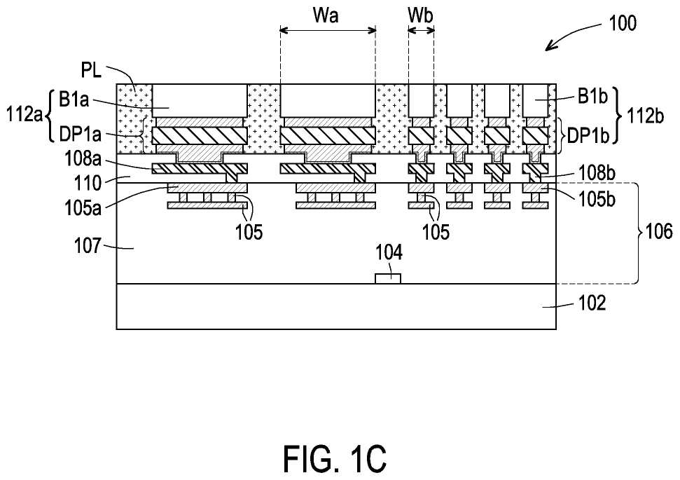

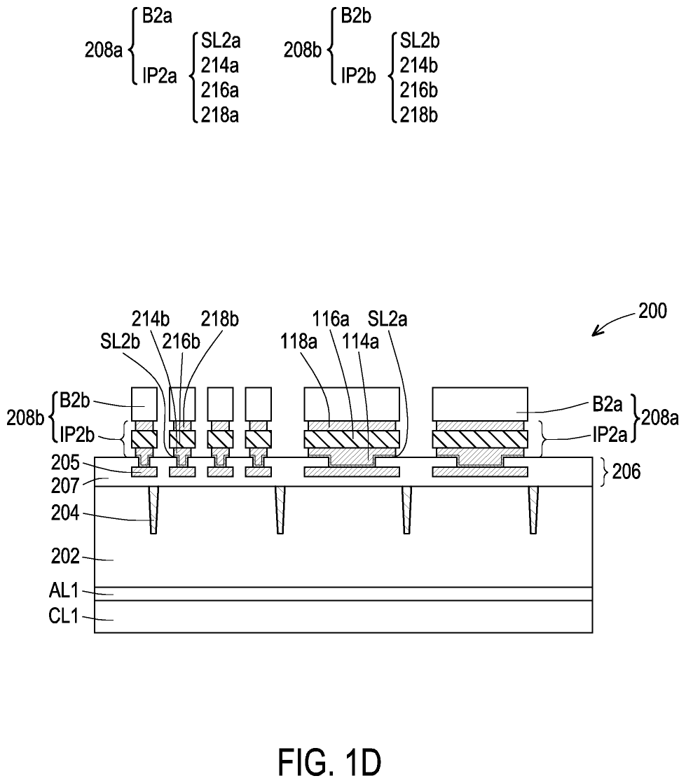

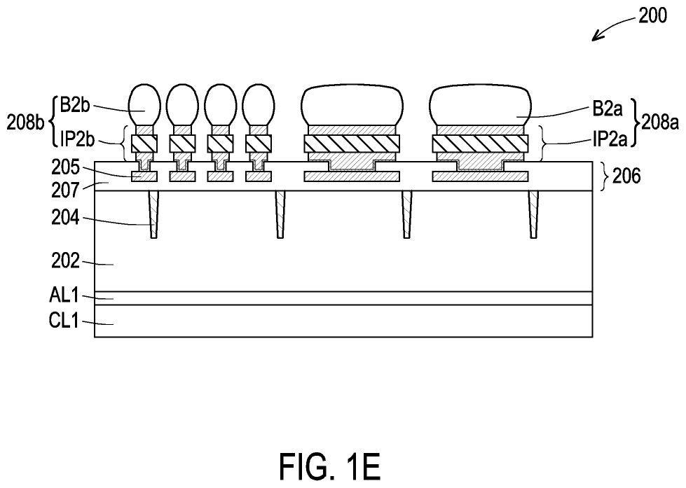

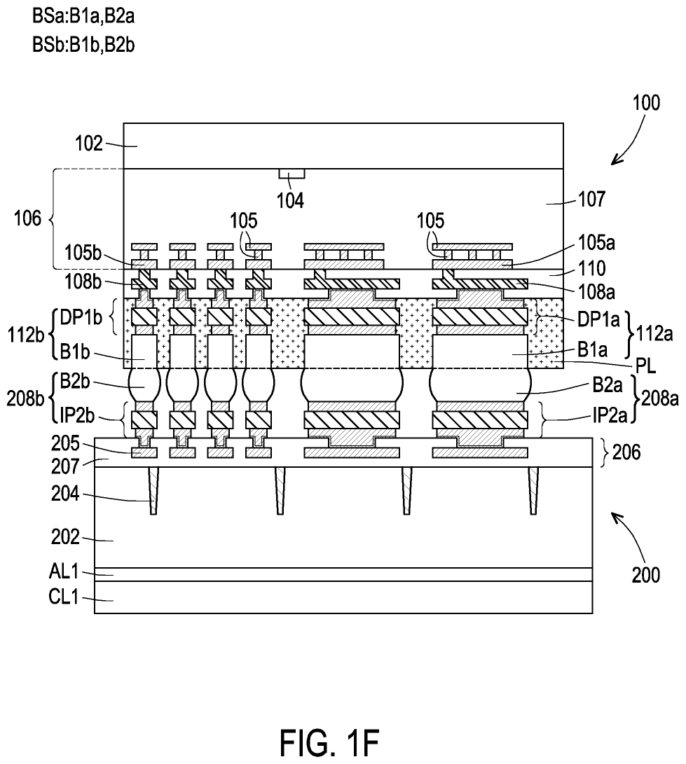

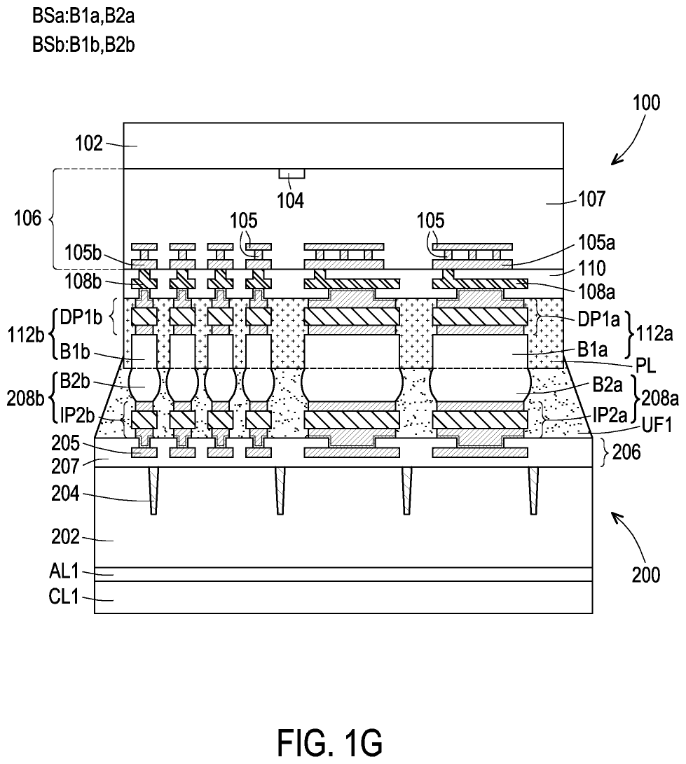

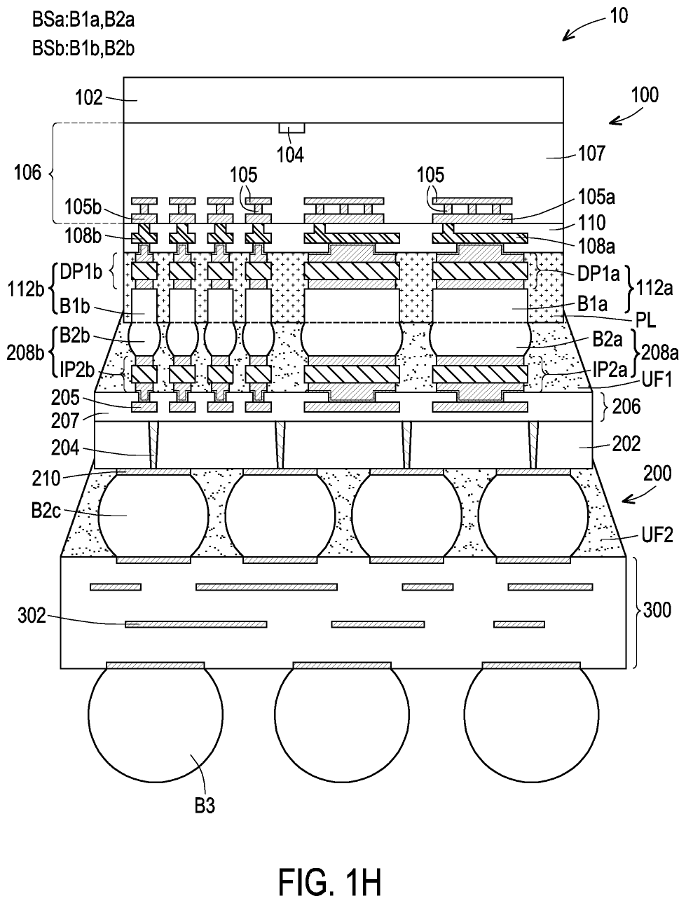

FIG. 1A to FIG. 1H are schematic cross-sectional views of a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 1A to FIG. 1H are described in relation to a method, it is appreciated that the structures disclosed in FIG. 1A to FIG. 1H are not limited to such a method, but instead may stand alone as structures independent of the method.

Referring to FIG. 1A, a semiconductor die 100 is provided. The semiconductor die 100 may be an application-specific integrated circuit (ASIC) chip, an analog chip, a sensor chip, a wireless and radio frequency chip, a voltage regulator chip or a memory chip, for example. In some embodiments, the semiconductor die 100 includes a substrate 102, at least one device 104 disposed on/in the substrate 102, and an interconnect structure 106 over the device 104.

In some embodiments, the substrate 102 includes an elementary semiconductor such as silicon or germanium and/or a compound semiconductor such as silicon germanium, silicon carbide, gallium arsenic, indium arsenide, gallium nitride or indium phosphide. In some embodiments, the substrate 102 is a semiconductor-on-insulator (SOI) substrate. In various embodiments, the substrate 102 may take the form of a planar substrate, a substrate with multiple fins, nanowires, or other forms known to people having ordinary skill in the art. The substrate 102 may be doped as needed.

In some embodiments, the substrate 102 includes isolation structures defining at least one active area, and at least one device 104 is disposed on/in the active area. In some embodiments, the device 104 includes an active component, a passive component, or a combination thereof. The device 104 may include a planar transistor, a fin field effect transistor (FinFET), a gate all around FET (GAA-FET) or the like.

In some embodiments, the interconnect structure 106 is disposed over a first side (e.g., front side or active side) of the substrate 102 and electrically connected to the device 104. In some embodiments, the interconnect structure 106 includes conductive features 105 embedded by one or more dielectric layers 107. The conductive features 105 include metal lines, metal vias, metal pads and/or metal connectors. In some embodiments, each conductive feature 105 includes Cu, Al, Ti, Ta, W, Ru, Co, Ni, the like, or a combination thereof. In some embodiments, a seed layer may be disposed between each conductive feature 105 and the adjacent dielectric layer 107. The seed layer may include Ti/Cu. In some embodiments, each dielectric layer 107 includes silicon oxide, silicon nitride, silicon oxynitride, silicon oxycarbide, the like, or a combination thereof. An etching stop layer may be interposed between two adjacent dielectric layers 107. The conductive features 105 include top metal features 105a and 105b, and top surfaces of the top metal features 105a and 105b are flushed with the topmost dielectric layer 107. The top metal features 105a and 105b are thicker than the underlying metal features 105. In some embodiments, the maximum width of the top metal features 105a is different from (e.g., greater than) the maximum width of the top metal features 105b.

In some embodiments, the semiconductor die 100 further includes conducive pads or testing pads 108a and 108b covered by one or more passivation layers 110 and connected to the top metal features 107a and 107b. The testing pads 108a and 108b are designed for a probe testing process to determine whether the semiconductor die 100 is a known good die (KGD) or not. The testing pads 108a and 108b may have probe marks after the probe testing process. In some embodiments, the testing pads 108a and 108b include aluminum pads or aluminum-copper pads. In some embodiments, the maximum width of the testing pads 108a is different from (e.g., greater than) the maximum width of the testing pads 108b. In some embodiments, the passivation layer 110 includes an insulating material such as silicon oxide, silicon nitride, silicon, silicon carbide, the like, or a combination thereof. However, the disclosure is not limited thereto. In other embodiments, the passivation layer 110 includes a polymer material such as polybenzoxazole (PBO), polyimide (PI), benzocyclobutene (BCB), the like, or a combination thereof.

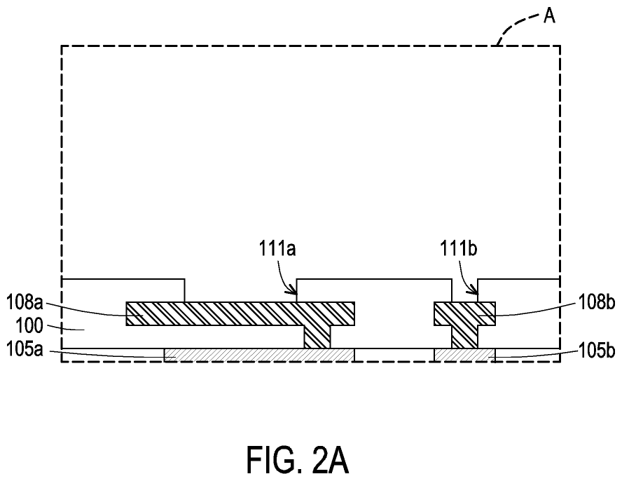

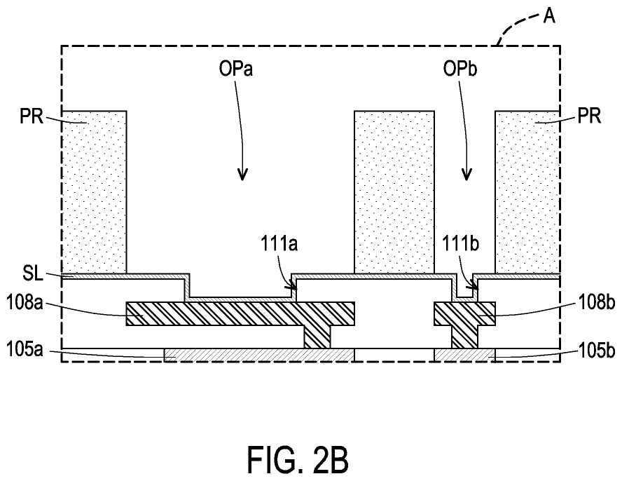

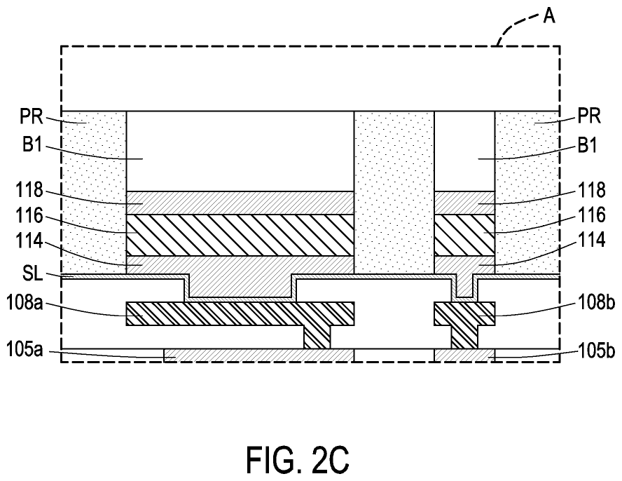

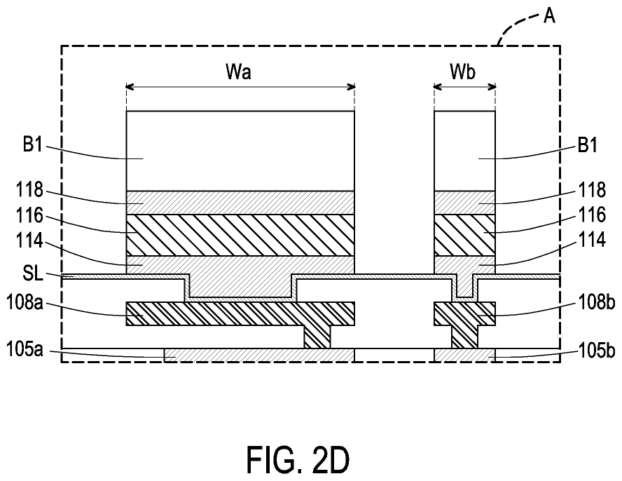

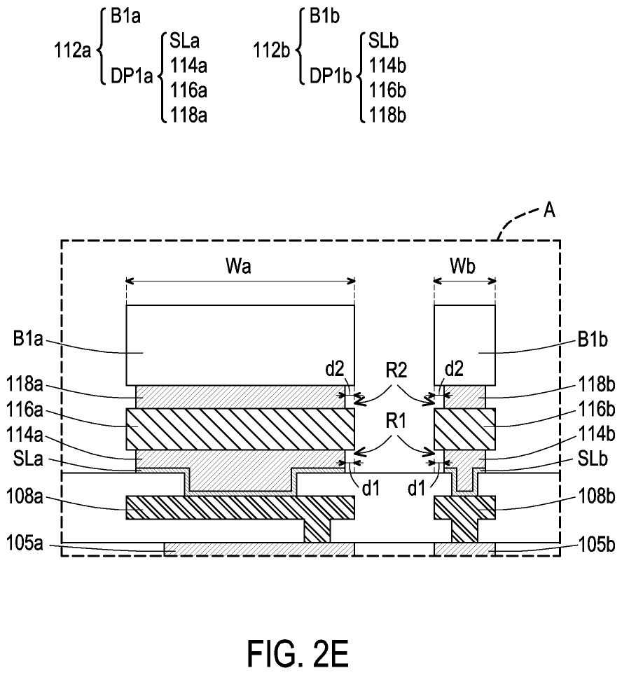

Still referring to FIG. 1A, die connectors 112a and 112b are formed over the first side of the semiconductor die 100 and electrically connected to the testing pads 108a and 108b. In some embodiments, each die connector 112a includes a die pad DP1a and an overlying die bump B1a and is landed on the corresponding testing pad 108a, and each die connector 112b includes a die pad DP1b and an overlying die bump B1b and is landed on the corresponding testing pad 108b. The die bumps B1a and B1b are referred to as “micro bumps” in some examples. The die pads may be referred to as “under bump metallization (UBM) pads” in some examples. The UBM pad may have a multi-layer structure (e.g., a two-layer structure, a three-layer structure, or a four-layer structure) or may be a single layer. In some embodiments, the die connectors 112a have a width Wa, and the die connectors 112b have a width Wb different from the width Wa. The method of forming the die connectors 112a and 112b in the region R of FIG. 1A is described with reference to FIG. 2A to FIG. 2E.

Referring to FIG. 2A, a patterning process is performed to form openings 111a and 111b in the passivation layer 110. The patterning process may include photolithography and etching processes. Specifically, the openings 111a and 111b penetrate through the passivation layer 110 and expose the underlying testing pads 108a and 108b, respectively.

Referring to FIG. 2B, a seed layer SL is formed conformally on the passivation layer 110 and fills in the openings 111a and 111b. Specifically, the seed layer SL is formed on the top surface of the passivation layer 110 and on the sidewalls and bottoms of the openings 111a and 111b, and is in contact with the testing pads 108a and 108b. The seed layer SL may include Ti/Cu and may be formed by a sputtering process.

Thereafter, a photoresist layer PR with opening patterns OPa and OPb is formed on the seed layer SL. The opening patterns OPa and OPb of the photoresist layer PR are formed by a photolithography process. Specifically, the opening patterns OPa and OPb correspond to the underlying testing pads 108a and 108b, respectively. In some embodiments, the opening patterns OPa have a width Wa, and opening patterns OPb have a width Wb different from (e.g., greater than) the width Wa. However, the disclosure is not limited thereto. In other embodiments, the width Wa of the opening patterns OPa may be substantially the same as the width Wb of the opening patterns OPb. For example, the ratio of the width Wa to the width Wb ranges from about 1:1 to 10:1, such as about 2:1, 3:1, 4:1, 5:1, 6:1, 7:1, 8:1 or 9:1, or in a suitable range between any two of the above ratios.

Referring to FIG. 2C, a first metal layer 114, a second metal layer 116 and a third metal layer 118, and a solder layer B1 are sequentially plated in the opening patterns OPa and OPb by using the seed layer SL as a seed. The first metal layer 114 is further formed in the openings 111a and 111b of the passivation layer 110. In some embodiments, the material of the second metal layer 116 is different from the material of the first metal layer 114 or the material of the third metal layer 118. In some embodiments, the first metal 114 and the third metal layer 118 include the same material. The second metal layer 116 serves as a blocking layer to prevent the solder layer B1 from flowing to the underlying or neighboring electrical components. In some embodiments, each of the first metal layer 114 and the third metal layer 118 includes a copper-containing material, such as Cu, Cu—Al, Cu—Zn, or a suitable Cu alloy. In some embodiments, the second metal layer 116 includes a copper-free material, such as a nickel-containing material (e.g., Ni, Ni—Al, Ni—Ti or a suitable Ni alloy), an iron-containing material (e.g., Fe, Fe—Ni or a suitable Fe alloy) or a cobalt-containing material (e.g., Co, Co—Cr or a suitable Co alloy). In some embodiments, the solder layer B1 is a lead-free solder material. In some embodiments, the solder layer B1 includes Sn, Sn—Ag, Sn—Cu, Su-Ag—Cu, Sn—Ag—Cu—Zn, Sn—Ag—Cu—Mn or a suitable Sn alloy.

Referring to FIG. 2D, the photoresist layer PR is removed. The photoresist layer PR may be removed by a stripping process, such as an etching process. At the stage, the sidewalls of the first metal layer 114, the second metal layer 116, the third metal layer 118, and the solder layer B1 in each of the opening patterns OPa and OPb are flushed with each other, as shown in FIG. 2D.

Referring to FIG. 2E, the seed layer SL, the first metal layer 114 and the third metal layer 118 are partially removed, and the die connectors 112a and 112b of the disclosure are thus completed. In some embodiments, each die connector 112a includes a die pad DP1a and an overlying die bump B1a, and each die connector 112b includes a die pad DP1b and an overlying die bump B1b. At this stage, each of the die connectors 112a and 112b has a wavy sidewall, as shown in FIG. 2E. Such partial removing process may be referred to as a “trimming process” in some examples, so that each of the trimmed first die pads 112a and the trimmed second die pads 112b has a middle-wide profile that the middle portion (e.g., second metal layer 116a/116b) is wider than the bottom portion (e.g., first metal layer 114a/114b) or the top metal portion (e.g., third metal layer 118a/118b). In some embodiments, the Cu-containing materials may be removed simultaneously during the same etching process, so the seed layer SL, the first metal layer 114 and the third metal layer 118 are recessed with respect to the second metal layer 116 or the solder layer B1. In some embodiments, an undercut or recess R1 is generated between the adjacent first metal layer 114a/114b and the second metal layer 116a/116b, and an undercut or recess R2 is generated between the adjacent second metal layer 116a/116b and the third metal layer 118a/118b. Specifically, the recessed distance d1 from the sidewall of the first metal layer 114a/114b to the sidewall of the second metal layer 116a/116b is greater than zero, and the recessed distance d2 from the sidewall of the third metal layer 118a/118b to the sidewall of the second metal layer 116a/116b is greater than zero. From another point of view, the sidewall of the second metal layer 116a/116b protrudes from the sidewall of the underlying first metal layer 114a/114b and the seed layer SLa/SLb, while the sidewall of the second metal layer 116a/116b is flushed with the sidewall of the solder layer B1a/B1b. In some embodiments, the die connectors 112a and 112b are regarded as part of the semiconductor die 100, and the die connectors 112a and 112b protrude from a first side (e.g., front side or active side) of the semiconductor die 100. In some embodiments, the conventional reflow process is not performed to the die connectors 112a and 112b, so that each of the solder layers B1a and B1b of the semiconductor die 100 has a rectangle-like shape. Specifically, each of the solder layers B1a and B1b has substantially straight sidewalls and a planar top surface connecting the substantially straight sidewalls, and the connecting corners are sharp corners.

In some embodiments, the die connectors 112a have a width Wa, and die connectors 112b have a width Wb different from (e.g., greater than) the width Wa. The widths Wa and Wb may be the maximum widths of the die connectors 112a and 112b. In some embodiments, the width Wa is about 30-100 um, and the width Wb is about 3-10 um. However, the disclosure is not limited thereto. In other embodiments, the width Wa of the die connectors 112a may be substantially the same as the width Wb of the die connectors 112b. In some embodiments, the width Wa is about 3-10 um, and the width Wb is about 3-10 um. In some embodiments, the ratio of the width Wa to the width Wb ranges from about 10:1 to 1:1, such as about 9:1, 8:1, 7:1, 6:1, 5:1, 4:1, 3:1 or 2:1, or in a suitable range between any two of the above ratios.

In some embodiments, due to different widths of the die connectors 112a and 112b, the heights of the die connector 112a and 112b are different due to process variation. For example, the height of the wider die connectors 112a may be less than the height of the narrower die connectors 112b by about 3 um or less. The die connectors 112a and 112b with different heights may have different tilt angles with respect to the surface of the passivation layer 110. The above-mentioned high and low connectors and connector tilt defects can be resolved by the operations of FIG. 1B and FIG. 1C of the disclosure.

Referring to FIG. 1B, a polymer layer PL is formed on the first side of the semiconductor die 100, and the polymer layer PL overs the die connectors 112a and 112b. In some embodiments, the polymer layer PL may include polyimide (PI), polybenzoxazole (PBO), benzocyclobutene (BCB) or the like, or combinations thereof, and may be formed by a spin-on coating process, a deposition process, or a molding process. In some embodiments, the polymer layer PL covers the tops and sidewalls of the die connectors 112a and 112b.

Referring to FIG. 1C, the polymer layer PL is planarized until surfaces of the die connectors 112a and 112b are exposed. The planarization process includes a chemical mechanical polishing (CMP) process, for example. The planarization process may be referred to as a “grinding process” or a “polishing process” in some examples. In some embodiments, a portion of the polymer layer PL and portions of die connectors 112a and 112b are removed by the same planarization process. After the planarization process is performed, the surface of the polymer layer PL is substantially coplanar with or flushed with exposed surfaces of the die connectors 112a and 112b. Such polishing may resolve the high and low connectors and connector tilt defects simultaneously, so as to improve the connecting property and therefore the package performance. In some embodiments, a laser grooving (LGV) protection film may be attached on the polymer layer PL in the subsequent LGV process for separating adjacent dies, and such LGV protection film may be removed before the bonding process (e.g., FIG. 1F). Such LGV protection film may be easier to be coated on the flat polymer layer PL, so the conventional LGV debris during the removal of the protection film may be avoided.

Referring to FIG. 1D, an interposer structure 200 is provided and attached to a carrier CL1. In some embodiments, the carrier CL1 includes a glass carrier or a suitable carrier. In some embodiments, the interposer structure 200 is attached to the carrier CL1 through an adhesive layer AL1. The adhesive layer AL1 may include an oxide layer, a die attach tape (DAF) or a suitable adhesive. The interposer structure 200 is in wafer form at this stage.

In some embodiments, the interposer structure 200 includes a substrate 202, through substrate vias 204 and a conductive structure 206. The substrate 202 may include elementary semiconductor such as silicon, germanium and/or a compound semiconductor such as silicon germanium, silicon carbide, gallium arsenic, indium arsenide, gallium nitride or indium phosphide. The substrate 202 may be doped as needed. The through substrate vias 204 (also called “through silicon vias” in some examples) extend from a first side (e.g., front side) of the substrate 202 towards a second side (e.g., back side) of the substrate 202. The through substrate vias 204 may not penetrate through the substrate 202 at this stage.

In some embodiments, the conductive structure 206 is disposed over the first side of the substrate 202 and electrically connected to the through substrate vias 204. In some embodiments, the conductive structure 206 includes conductive features 205 embedded by one or more dielectric layers 207. The conductive features 205 include metal lines, metal vias, metal pads and/or metal connectors. In some embodiments, each conductive feature 205 includes Cu, Al, Ti, Ta, W, Ru, Co, Ni, the like, or a combination thereof. In some embodiments, a seed layer may be disposed between each conductive feature 205 and the adjacent dielectric layer 207. The seed layer may include Ti/Cu. In some embodiments, each dielectric layer 207 includes silicon oxide, silicon nitride, silicon oxynitride, silicon oxycarbide, the like, or a combination thereof.

In some embodiments, the interposer structure 200 is an active interposer that contains at least one functional device or integrated circuit device included in the conductive structure 206. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 200 is a passive interposer, which is lack of a functional device or integrated circuit device. Such passive interposer is referred to as a “device-free interposer” in some examples.

In some embodiments, interposer connectors 208a and 208b are formed over the first side of the interposer structure 200 and electrically connected to the conductive features 205. In some embodiments, each interposer connector 208a includes an interposer pad IP2a and an overlying interposer bump B2a and is landed on the corresponding conductive feature 205, and each interposer connector 208b includes an interposer pad IP2b and an overlying interposer bump B2b and is landed on the corresponding conductive feature 205. The interposer pads may be referred to as “under bump metallization (UBM) pads” in some examples. The UBM pad may have a multi-layer structure (e.g., a two-layer structure, a three-layer structure, or a four-layer structure) or may be a single layer. The interposer bump B2a and B2b are referred to as “micro bumps” in some examples. In some embodiments, the maximum width of the interposer connectors 208a is different from (e.g., greater than) the maximum width of the interposer connectors 208b. The method of forming the interposer connectors 208a and 208b are similar to the method of forming the die connectors 112a and 112b. The operations of forming the interposer connectors 208a and 208b may refer to those described in FIG. 2A to FIG. 2E, so the details are not iterated herein. In some embodiments, each of the interposer connector 208a and 208b has a wavy sidewall, as shown in FIG. 1D. In some embodiments, the interposer connector 208a and 208b are regarded as part of the interposer structure 200, and the interposer connector 208a and 208b protrude from a first side (e.g., front side or active side) of the interposer structure 200.

In some embodiments, each of the interposer connector 208a and 208b has a middle-wide profile that the middle portion (e.g., second metal layer 216a/216b) is wider than the bottom portion (e.g., first metal layer 214a/214b) or the top metal portion (e.g., third metal layer 218a/218b). In some embodiments, an undercut or recess is generated between the adjacent first metal layer 214a/2214b and the second metal layer 216a/216b, and an undercut or recess is generated between the adjacent second metal layer 216a/216b and the third metal layer 218a/218b. Specifically, the recessed distance from the sidewall of the first metal layer 214a/214b to the sidewall of the second metal layer 216a/216b is greater than zero, and the recessed distance from the sidewall of the third metal layer 218a/218b to the sidewall of the second metal layer 216a/216b is greater than zero. From another point of view, the sidewall of the second metal layer 216a/216b protrudes from the sidewall of the underlying first metal layer 214a/214b and the seed layer SL2a/SL2b, while the sidewall of the second metal layer 216a/216b is flushed with the sidewall of the solder layer B2a/B2b.

In some embodiments, the material of the second metal layer 216a/216b is different from the material of the first metal layer 214a/214b or the material of the third metal layer 218a/218b. In some embodiments, the first metal 214a/214b and the third metal layer 218a/218b include the same material. The second metal layer 216a/216b serves as a blocking layer to prevent the solder layer Ba/B2b from flowing to the underlying or neighboring electrical components. In some embodiments, each of the first metal layer 214a/214b and the third metal layer 218a/218b includes a copper-containing material, such as Cu, Cu—Al, Cu—Zn, or a suitable Cu alloy. In some embodiments, the second metal layer 216a/216b includes a copper-free material, such as a nickel-containing material (e.g., Ni, Ni—Al, Ni—Ti or a suitable Ni alloy), an iron-containing material (e.g., Fe, Fe—Ni or a suitable Fe alloy) or a cobalt-containing material (e.g., Co, Co—Cr or a suitable Co alloy). In some embodiments, the solder layer B2a/B2b is a lead-free solder material. In some embodiments, the solder layer B2a/B2b includes Sn, Sn—Ag, Sn—Cu, Su-Ag—Cu, Sn—Ag—Cu—Zn, Sn—Ag—Cu—Mn or a suitable Sn alloy.

Referring to FIG. 1E, a reflow process is performed to reflow the solder layers B2a and B2b. After the reflow process, each of the rectangular solder layers B2a and B2b is shaped to an oval-like solder layer B2a and B2b having a rounded surface. The reflow process may range of about 200-260° C. for a time of about 1-2 minutes, but other temperatures may be achieved for other times in other exemplary embodiments.

Referring to FIG. 1F, one or more semiconductor dies 100 are placed on and bonded to the interposer structure 200 in wafer form. In some embodiments, the die connectors 112a and 112b of the semiconductor die 100 are bonded to interposer connectors 208a and 208b of an interposer structure 200. Specifically, the die bumps B1a and B1b of the semiconductor die 100 are in contact with the interposer bumps B2a and B2b of the interposer structure 200. In some embodiments, the die bumps B1a and the interposer bumps B2a constitute bump structures BSa, and the die bumps B1b and the interposer bumps B2b constitute bump structures BSb. In some embodiments, each of the bump structures BSa has a turning point at the interface between the die bump B1a and the interposer bump B2a, and each of the bump structures BSb has a turning point at the interface between the die bump B1b and the interposer bump B2b. The material of the die bumps B1a and B1b may be the same as the material of the interposer bumps B2a and B2b, so the interfaces between the die bumps B1a and the interposer bumps B2a and between the die bumps B1b and the interposer bumps B2b are invisible.

Referring to FIG. 1G, an underfill layer UF1 is formed around the interposer connectors 208a and 208b. In some embodiments, the underfill layer UF1 is contact with the polymer layer PL and further climbs onto the lower sidewall of the polymer layer PL. In some embodiments, the underfill layer UF1 includes a molding compound such as epoxy, and is formed using dispensing, injecting, and/or spraying process.

In some embodiments, an encapsulation layer may be formed over the interposer structure 200 and may laterally encapsulate the sidewalls of the semiconductor die 100. The top surface of the encapsulation layer may be substantially coplanar with or flushed with the second side (e.g., back side or non-active side) of the semiconductor die 100. The encapsulation layer may include a polymer material such as polybenzoxazole (PBO), polyimide, benzocyclobutene (BCB), the like, or a combination thereof. The encapsulation layer may be formed by a molding process followed by a curing process.

Referring to FIG. 1H, the carrier CL1 is debonded from the overlying structure. In one embodiment, the debonding process is a laser debonding process or a suitable process. The adhesive layer AL1 is removed from the interposer structure 200. In some embodiments, the removing process is an etching process and/or a cleaning process.

Thereafter, a polishing process is performed to the interposer structure 200, until the through substrate vias 204 are exposed. In some embodiments, a chemical mechanical polishing (CMP) process is performed to thin the substrate 202 and the through substrate vias 204 of the interposer structure 200. In some embodiments, metal pads 210 (or called UBM pads) are formed below and electrically connected to the through substrate vias 204. Afterwards, bumps B2c are formed below and electrically connected to the metal pads 210. In some embodiments, the bumps B2c include solder bumps, and/or may include metal pillars (e.g., copper pillars), solder caps formed on metal pillars, and/or the like. The bumps B2c are referred to as “controlled collapse chip connection (C4) bumps” in some examples. The bumps B2c may be formed by a suitable process such as evaporation, electroplating, ball drop, or screen printing. The size (e.g., the maximum width) of the bumps B2c may be different from (e.g., greater than) the size (e.g., the maximum width) of the bump structures BSa and BSb.

In some embodiments, a wafer dicing process is performed, so as to separate adjacent structures from each other. Specifically, the interposer structure 200 in wafer form is cut into multiple singulated interposer structures 200, and each interposer structure 200 is bonded to the corresponding semiconductor die 100.

Thereafter, after the wafer dicing process, a board substrate 300 is formed below and electrically connected to the interposer structure 200. In some embodiments, the board substrate 300 is bonded to the interposer structure 200 through the bumps B2c.

In some embodiments, the board substrate 300 includes a core layer and two build-up layers on opposite sides of the core layer. In some embodiments, the core layer includes prepreg (which contains epoxy, resin, and/or glass fiber), polyimide, photo image dielectric (PID), the like, or a combination thereof. In some embodiments, the build-up layers include prepreg (which contains epoxy, resin, and/or glass fiber), polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), the like, or a combination thereof. The material of the core layer may be different from the material of the build-up layers. In some embodiments, the board substrate 300 includes wiring patterns 302 that may penetrate through the core layer and the build-up layers for providing electrical routing between different interposers, dies or die stacks. The wiring patterns 302 include lines, vias, pads and/or connectors. The board substrate 300 is referred to as a “printed circuit board (PCB)” in some examples. In other embodiments, the core layer of the board substrate 300 may be omitted as needed, and such board substrate 300 is referred to as a “coreless board substrate”.

Next, an underfill layer UF2 is formed to fill the space between the interposer structure 200 and the board substrate 300, and surrounds the bumps B2c. In some embodiments, the underfill layer UF2 includes a molding compound such as epoxy, and is formed using dispensing, injecting, and/or spraying process.

Afterwards, bumps B3 are formed below and electrically connected to the board substrate 300. In some embodiments, bump B3 are electrically connected to the wiring patterns 302 of the board substrate 300. In some embodiments, the bumps B3 include solder bumps, and/or may include metal pillars (e.g., copper pillars), solder caps formed on metal pillars, and/or the like. The bumps B3 are referred to as “ball grid array (BGA) balls” in some examples. The bumps B3 may be formed by a suitable process such as evaporation, electroplating, ball drop, or screen printing. The size (e.g., the maximum width) of the bumps B3 may be different from (e.g., greater than) the size (e.g., the maximum width) of the bumps B2. In some embodiments, the semiconductor package 10 of the disclosure is thus completed.

In the disclosure, by introducing a polymer layer around die connectors of a semiconductor die followed by a planarization process, the die connectors with different heights and connector tilt defects can be resolved simultaneously, so as to improve the connecting property and therefore the package performance.

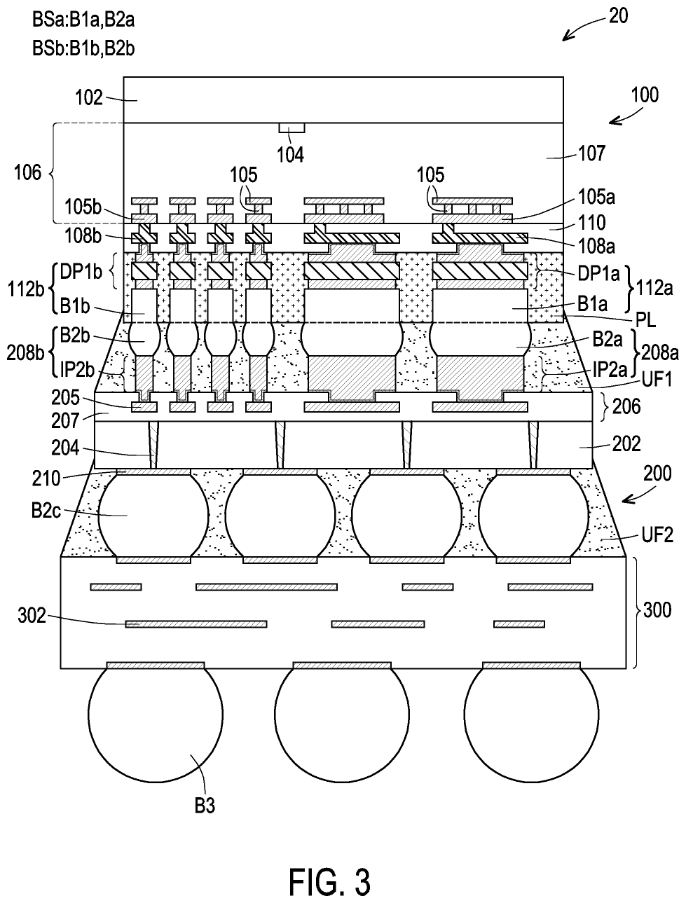

The above embodiments in which each of the die pads and the interposer pads has a multi-layer structure (e.g., a three-layer structure) are provided for illustration purposes, and are not construed as limiting the present disclosure. Each of the die pads and the interposer pads may be chosen to have a multi-layer structure (e.g., a two-layer structure, a three-layer structure, or a four-layer structure) or a single-layer structure upon the process requirements. Some examples are shown in FIG. 3 to FIG. 5, but other modified examples are also possible

FIG. 3 to FIG. 5 are schematic cross-sectional views of semiconductor packages in accordance with some embodiments.

The semiconductor package 20 of FIG. 3 is similar to the semiconductor package 10 of FIG. 1H, and the difference between them lies in that, each of the interposer pads of FIG. 3 is a single-layer pad having substantially vertical sidewalls, while each of the interposer pads of FIG. 1H is a multi-layer pad having wavy sidewalls.

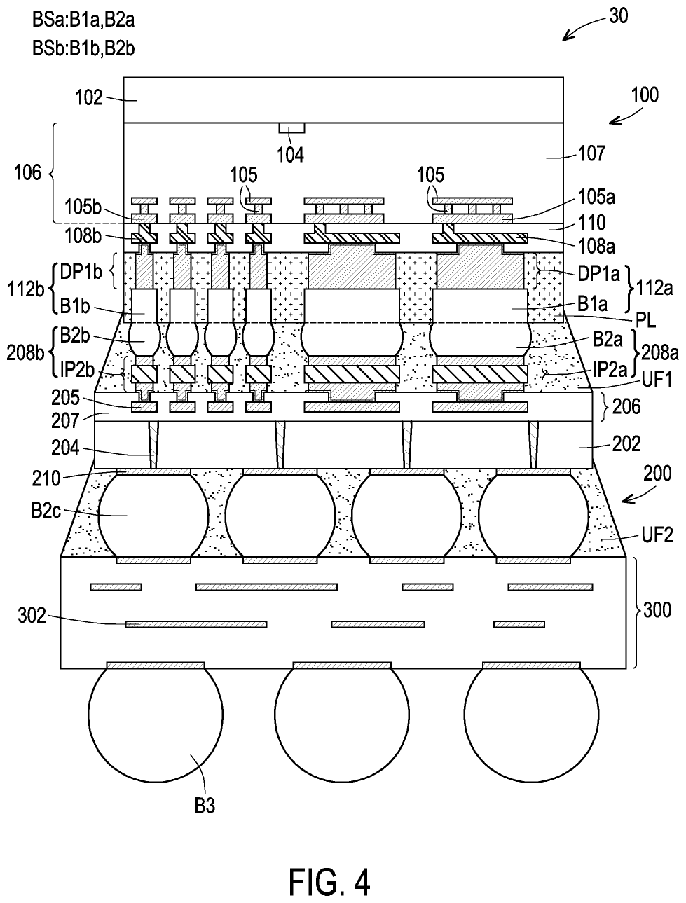

The semiconductor package 30 of FIG. 4 is similar to the semiconductor package 10 of FIG. 1H, and the difference between them lies in that, each of the die pads of FIG. 4 is a single-layer pad having substantially vertical sidewalls, while each of the die pads of FIG. 1H is a multi-layer pad having wavy sidewalls.

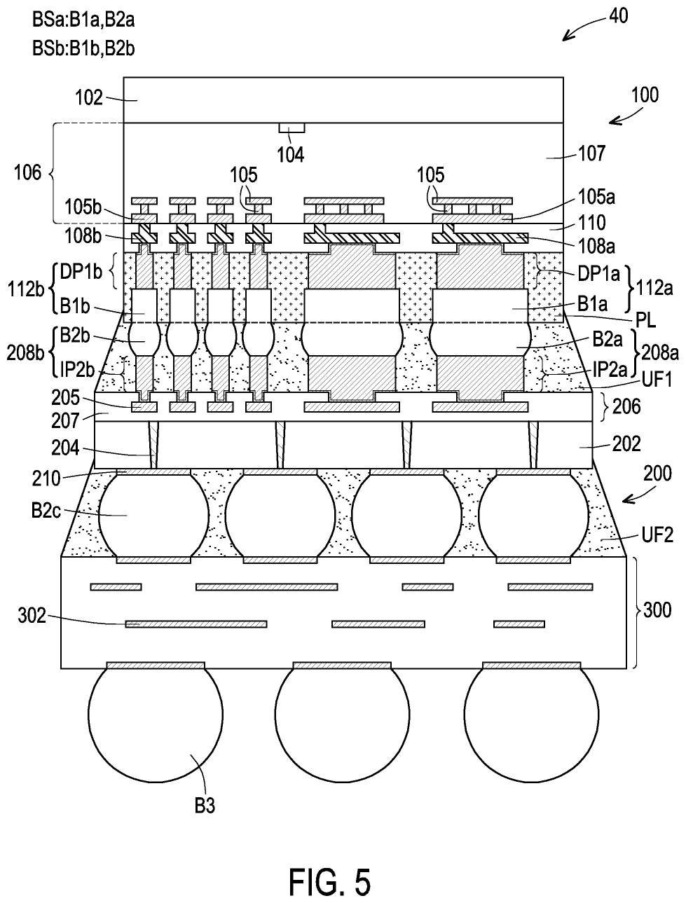

The semiconductor package 40 of FIG. 5 is similar to the semiconductor package 10 of FIG. 1H, and the difference between them lies in that, each of the interposer pads and die pads of FIG. 3 is a single-layer pad having substantially vertical sidewalls, while each of the interposer pads and die pads of FIG. 1H is a multi-layer pad having wavy sidewalls.

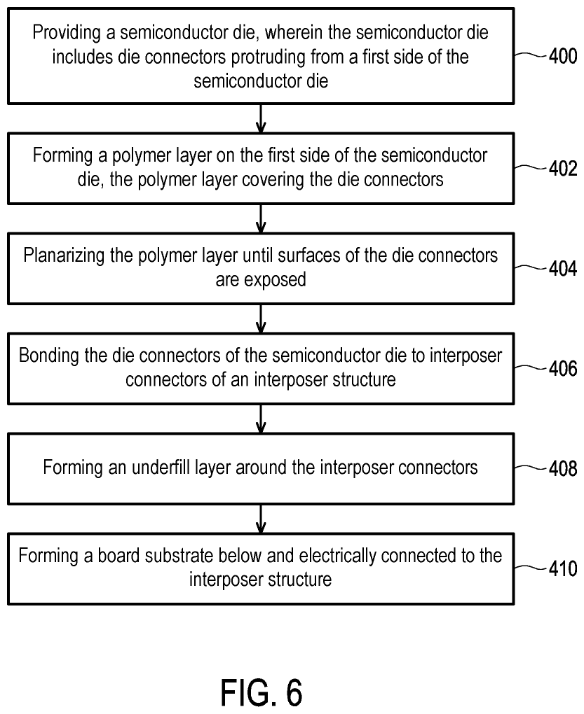

FIG. 6 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 400, a semiconductor die is provided, wherein the semiconductor die includes die connectors protruding from a first side of the semiconductor die. In some embodiments, a method of forming the die connectors of the semiconductor die includes: forming a seed layer on the first side of the semiconductor die (see FIG. 2A and FIG. 2B); forming a photoresist layer with opening patterns on the seed layer (see FIG. 2B); plating a first metal layer, a second metal layer, a third metal layer and a solder layer sequentially in the opening patterns (see FIG. 2C); removing the photoresist layer (see FIG. 2D); and partially removing the seed layer, the first metal layer and the third metal layer (see FIG. 2E). In some embodiments, a material of the second metal layer is different from a material of the first metal or a material of the third metal layer. In some embodiments, the die connectors include first die connectors having a first width and second die connectors having a second width different from the first width. FIG. 1A and FIG. 2A to FIG. 2E illustrate cross-sectional views corresponding to some embodiments of act 400.

At act 402, a polymer layer is formed on the first side of the semiconductor die, and the polymer layer covers the die connectors. FIG. 1B illustrates a cross-sectional view corresponding to some embodiments of act 402.

At act 404, the polymer layer is planarized until surfaces of the die connectors are exposed. In some embodiments, after planarizing the polymer layer, a surface of the polymer layer is flushed with exposed surfaces of the die connectors. FIG. 1C illustrates a cross-sectional view corresponding to some embodiments of act 404.

At act 406, the die connectors of the semiconductor die are bonded to interposer connectors of an interposer structure. In some embodiments, the die connectors include die pads and die bumps, the interposer connectors include interposer pads and interposer bumps, and a shape of the die bumps is different from a shape of the interposer bumps. FIG. 1D to FIG. 1F illustrate cross-sectional views corresponding to some embodiments of act 406.

At act 408, an underfill layer is formed around the interposer connectors. In some embodiments, the underfill layer further creeps onto a sidewall of the polymer layer. FIG. 1G illustrates a cross-sectional view corresponding to some embodiments of act 408.

At act 410, a board substrate is formed below and electrically connected to the interposer structure. FIG. 1H illustrates a cross-sectional view corresponding to some embodiments of act 410.

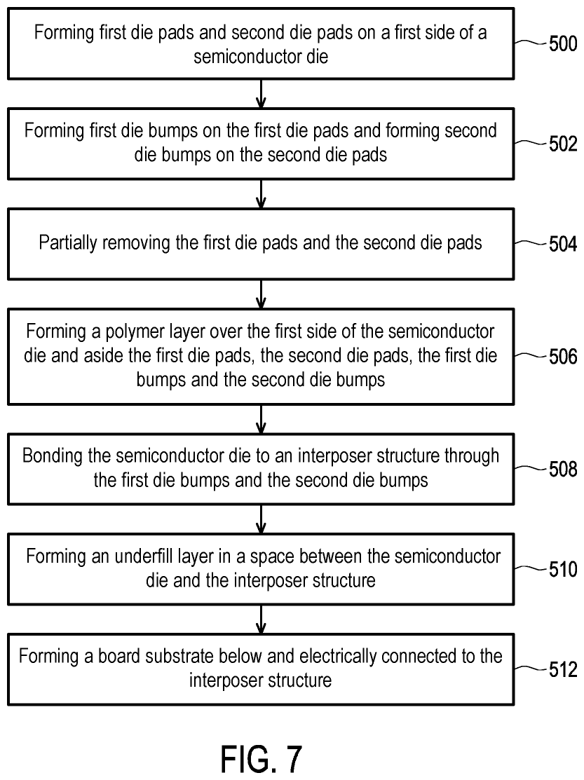

FIG. 7 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 500, first die pads and second die pads are formed on a first side of a semiconductor die. In some embodiments, the first die pads having a first width and the second die pads having a second width different from the first width. FIG. 1A and FIG. 2A to FIG. 2D illustrate cross-sectional views corresponding to some embodiments of act 500.

At act 502, first die bumps are formed on the first die pads and forming second die bumps are formed on the second die pads. In some embodiments, the first die bumps having a first width and the second die bumps having a second width different from the first width. FIG. 1A and FIG. 2A to FIG. 2D illustrate cross-sectional views corresponding to some embodiments of act 502.

At act 504, the first die pads and the second die pads are partially removed. In some embodiments, partially removing the first die pads and the second die pads includes trimming the first die pads and the second die pads so that each of the trimmed first die pads and the trimmed second die pads has a middle-wide profile. FIG. 1A and FIG. 2E illustrate cross-sectional views corresponding to some embodiments of act 504.

At act 506, a polymer layer is formed over the first side of the semiconductor die and aside the first die pads, the second die pads, the first die bumps and the second die bumps. In some embodiments, a method of forming the polymer layer includes: forming a polymer material on the first side of the semiconductor die, the polymer material covering the first die pads, the second die pads, the first die bumps and the second die bumps (see FIG. 1B); and performing a polishing process to the polymer layer and the first die bumps and the second die bumps (see FIG. 1C). In some embodiments, after the polishing process, a surface of the polymer layer is flushed with surfaces of the first die bumps and surfaces of the second die bumps. FIG. 1B to FIG. 1C illustrate cross-sectional views corresponding to some embodiments of act 502.

At act 508, the semiconductor die is bonded to an interposer structure through the first die bumps and the second die bumps. FIG. 1D to FIG. 1F illustrate cross-sectional views corresponding to some embodiments of act 508.

At act 510, an underfill layer is formed in a space between the semiconductor die and the interposer structure. FIG. 1G illustrates a cross-sectional view corresponding to some embodiments of act 510.

At act 512, a board substrate is formed below and electrically connected to the interposer structure. FIG. 1H illustrates a cross-sectional view corresponding to some embodiments of act 512.

The semiconductor packages of the disclosure are illustrated below with reference to DIF. 1H and FIG. 3 to FIG. 5.

In some embodiments, a semiconductor package 10/20/30/40 includes an interposer structure 200, a semiconductor die 100 and a polymer layer PL. The interposer structure 200 includes interposer pads IP2a and IP2b and interposer bumps B2a and B2b over the interposer pads IP2a and IP2b. The semiconductor die 100 includes die pads DP1a and DP1b and die bumps B1a and B1b over the die pads DP1a and DP1b. The die bumps B1a and B1b of the semiconductor die 100 are in contact with the interposer bumps B2a and B2b of the interposer structure 200. The polymer layer PL laterally encapsulates the die pads DP1a and DP1b and the die bumps B1a and B1b. The shape or profile of the die bumps B1a and B1b is different from the shape or profile of the interposer bumps B2a and B2b.

In some embodiments, the die bumps B1a and B1b have substantially straight sidewalls, and the interposer bumps B2a and B2b have curve sidewalls. In some embodiments, the surface of the polymer layer PL is flushed with surfaces of the die bumps B1a and B1b. In some embodiments, the semiconductor package 100 further includes an underfill layer UF1 disposed around the interposer pads IP2a and IP2b and the interposer bumps B2a and B2b, wherein the underfill layer UF1 further covers a lower sidewall of the polymer layer PL. In some embodiments, each of the die pads DP2a and DP2b and the interposer pads IP2a and IP2b has a middle-wide profile.

In view of the foregoing, in the disclosure, by introducing a polymer layer around die connectors of a semiconductor die followed by a planarization process, the die connectors with different heights and connector tilt defects can be resolved simultaneously, so as to improve the connecting property and therefore the package performance.

Many variations of the above examples are contemplated by the present disclosure. It is understood that different embodiments may have different advantages, and that no particular advantage is necessarily required of all embodiments.

In accordance with some embodiments of the present disclosure, a semiconductor package includes the following operations. A semiconductor die is provided, wherein the semiconductor die includes die connectors protruding from a first side of the semiconductor die. A polymer layer is formed on the first side of the semiconductor die and covers the die connectors. The polymer layer is planarized until surfaces of the die connectors are exposed. The die connectors of the semiconductor die is bonded to interposer connectors of an interposer structure. An underfill layer is formed around the interposer connectors.

In accordance with alternative embodiments of the present disclosure, a method of forming a semiconductor package includes following operations. First die pads and second die pads are formed on a first side of a semiconductor die. First die bumps are formed on the first die pads and second die bumps are formed on the second die pads. The first die pads and the second die pads are partially removed. A polymer layer is formed over the first side of the semiconductor die and aside the first die pads, the second die pads, the first die bumps and the second die bumps. The semiconductor die is bonded to an interposer structure through the first die bumps and the second die bumps.

In accordance with yet alternative embodiments of the present disclosure, a semiconductor package includes an interposer structure, a semiconductor die and a polymer layer. The interposer structure includes interposer pads and interposer bumps over the interposer pads. The semiconductor die includes die pads and die bumps over the die pads, and the die bumps of the semiconductor die are in contact with the interposer bumps of the interposer structure. The polymer layer laterally encapsulates the die pads and the die bumps. A profile of the die bumps is different from a profile of the interposer bumps.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor package, comprising:
providing a semiconductor die, wherein the semiconductor die comprises die connectors protruding from a first side of the semiconductor die;
forming a polymer layer on the first side of the semiconductor die, the polymer layer covering the die connectors;
planarizing the polymer layer until surfaces of the die connectors are exposed;
bonding the die connectors of the semiconductor die to interposer connectors of an interposer structure; and
forming an underfill layer around the interposer connectors.

2. The method of claim 1, wherein the underfill layer further creeps onto a sidewall of the polymer layer.

3. The method of claim 1, wherein after planarizing the polymer layer, a surface of the polymer layer is flushed with exposed surfaces of the die connectors.

4. The method of claim 1, wherein a method of forming the die connectors of the semiconductor die comprises:
forming a seed layer on the first side of the semiconductor die;
forming a photoresist layer with opening patterns on the seed layer;
plating a first metal layer, a second metal layer, a third metal layer and a solder layer sequentially in the opening patterns;
removing the photoresist layer; and
partially removing the seed layer, the first metal layer and the third metal layer.

5. The method of claim 4, wherein a material of the second metal layer is different from a material of the first metal or a material of the third metal layer.

6. The method of claim 1, wherein the die connectors comprise first die connectors having a first width and second die connectors having a second width different from the first width.

7. The method of claim 1, wherein the die connectors comprise die pads and die bumps, the interposer connectors comprise interposer pads and interposer bumps, and a shape of the die bumps is different from a shape of the interposer bumps.

8. The method of claim 1, further comprising:
forming a board substrate below and electrically connected to the interposer structure.

9. A method of forming a semiconductor package, comprising:
forming first die pads and second die pads on a first side of a semiconductor die;
forming first die bumps on the first die pads and forming second die bumps on the second die pads;
partially removing the first die pads and the second die pads;
forming a polymer layer over the first side of the semiconductor die and aside the first die pads, the second die pads, the first die bumps and the second die bumps; and
bonding the semiconductor die to an interposer structure through the first die bumps and the second die bumps.

10. The method of claim 9, wherein a method of forming the polymer layer comprises:
forming a polymer material on the first side of the semiconductor die, the polymer material covering the first die pads, the second die pads, the first die bumps and the second die bumps; and
performing a polishing process to the polymer layer and the first die bumps and the second die bumps.

11. The method of claim 10, wherein after the polishing process, a surface of the polymer layer is flushed with surfaces of the first die bumps and surfaces of the second die bumps.

12. The method of claim 9, wherein partially removing the first die pads and the second die pads comprises trimming the first die pads and the second die pads.

13. The method of claim 9, wherein the first die pads having a first width and the second die pads having a second width different from the first width.

14. The method of claim 9, wherein the first die bumps having a first width and the second die bumps having a second width different from the first width.

15. The method of claim 9, further comprising forming an underfill layer in a space between the semiconductor die and the interposer structure.

16. A semiconductor package, comprising:
an interposer structure, comprising interposer pads and interposer bumps over the interposer pads;
a semiconductor die, comprising die pads and die bumps over the die pads, wherein the die bumps of the semiconductor die are in contact with the interposer bumps of the interposer structure; and
a polymer layer, laterally encapsulating the die pads and the die bumps.

17. The semiconductor package of claim 16, wherein the die bumps have substantially straight sidewalls, and the interposer bumps have curve sidewalls.

18. The semiconductor package of claim 16, wherein a surface of the polymer layer is flushed with surfaces of the die bumps.

19. The semiconductor package of claim 16, further comprising an underfill layer disposed around the interposer pads and the interposer bumps.

20. The semiconductor package of claim 19, wherein the underfill layer is in contact with the polymer layer.
